(19) United States
(12) Patent Application Publication
(10) Pub. No.: US 2008/0179707 A1
(43) Pub. Date: Jul. 31, 2008

(54) Semiconductor device having a fuse element

(75) Inventor: Sumio Ogawa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/010,399

(22) Filed: Jan. 24, 2008

(30) Foreign Application Priority Data
Jan. 26, 2007 (JP) 2007-016714

(51) Int. Cl. H01L 23/525

(52) U.S. Cl. 257/529; 257/E23.15

(57) ABSTRACT

A semiconductor device includes plural fuse elements that can be disconnected by irradiating a laser beam, lower-layer wirings that are located lower than the use elements, and plural through-hole electrodes for connecting between the fuse elements and the lower-layer wirings. The through-hole electrodes are provided at both ends of the fuse elements in the longitudinal direction, and a plurality of fuse elements are laid out on substantially a straight line in an A direction as a longitudinal direction. Accordingly, at the time of disconnecting a predetermined fuse element, through-hole electrodes connected to this fuse element become a shade, and unnecessary energy of a laser beam is not directly irradiated to other through-hole electrodes.

### TECHNICAL FIELD

The present invention relates to a semiconductor device, and more particularly relates to a semiconductor device having a fuse element which can be disconnected by irradiating a laser beam to this fuse element.

### BACKGROUND OF THE INVENTION

A memory density of semiconductor memory devices as represented by a DRAM (Dynamic Random Access Memory) increases year by year based on progress of microfabrication. However, along the progress of microfabrication, the number of defective memory cells included in one chip also increases in the actual situation. These defective memory cells are usually replaced by redundant memory cells, thereby relieving defective addresses.

In general, defective addresses are stored in a program circuit including plural fuse elements. When an access to a defective address is requested, the program circuit detects this access, and performs so that the alternate access is made to a redundant memory cell instead of this defective memory cell. As a configuration of the program circuit, there is known a system that allocates a pair of (that is, two) fuse elements to each bit constituting an address to be stored, and that stores a desired address by disconnecting one of the pair of fuse elements, as described in Japanese Patent Application Laid-open No. H9-69299.

There is also known a system that allocates one fuse element to each bit constituting an address to be stored, as described in Japanese Patent Application Laid-open No. H6-119796. According to this system, one bit can be stored depending on whether one fuse element is to be disconnected. Therefore, the number of fuse elements can be substantially decreased.

There are broadly two methods of disconnecting a fuse element: a method of disconnecting a fuse element by fusing the fuse element using a large current (see Japanese Patent Application Laid-open Nos. 2005-136060 and 2003-501835); and a method of disconnecting a fuse element by breaking the fuse element by irradiating a laser beam (see Japanese Patent Application Laid-open Nos. H7-74254 and H9-36234). The former method has advantages in that the method requires no expensive device such as a laser trimmer, and can easily self-diagnose whether a fuse element is correctly disconnected. However, in using this method, a fuse disconnecting circuit and a diagnosis circuit need to be incorporated in a semiconductor in advance. This has a disadvantage of increasing a chip area.

On the other hand, the method of breaking a fuse element by irradiating a laser beam does not require a fuse disconnecting circuit to be incorporated in a semiconductor device in advance. Therefore, a chip area can be decreased by this method.

FIG. 13 is a schematic cross-sectional view for explaining a method of disconnecting a conventional fuse element by irradiating a laser beam.

A fuse element 10 shown in FIG. 13 is located on a higher layer than lower-layer wirings 11, and both ends of the fuse element 10 are connected to the lower-layer wirings 11 via through-hole electrodes 12. To disconnect the fuse element 10 having this configuration, a laser beam L is irradiated to the fuse element 10 from above the fuse element 10. In this case, the laser beam L is converged to include the fuse element 10 within a focal depth of the laser beam L, thereby focusing heat energy onto the fuse element 10 to disconnect the fuse element 10.

Before the fuse element 10 is disconnected, the two lower-layer wirings 11 shown in FIG. 13 are electrically connected to each other. When the fuse element 10 is disconnected, the two lower-layer wirings 11 are electrically insulated. In this way, a connection state of the lower-layer wirings 11 can be irreversibly changed by using the fuse element 10. With this arrangement, a defective address can be stored permanently.

To store a defective address and the like, many fuse elements 10 need to be laid out. Therefore, at the time of disconnecting a predetermined fuse element by irradiating a laser beam, influence given to adjacent fuse elements and to their peripheries need to be considered.

FIG. 14 and FIG. 15 are explanatory views of the influence applied by the laser beam to other fuse elements and to their peripheries. FIG. 14 is a top plan view, and FIG. 15 is a schematic cross-sectional view along a line D-D shown in FIG. 14.

In the example shown in FIG. 14, parallel lower-layer wirings 11a to 11e are extended to a Y direction, and the layout pitch in an X direction is set as Xp. Fuse elements 10a to 10e connected to the lower-layer wirings 11a to 11e are laid out in zigzag manner, thereby securing a distance between two fuse elements adjacent in the X direction. One ends of the lower-layer wirings 11a to 11e are connected to a part of a program circuit (not shown), via the fuse elements 10a to 10e, respectively, and the other ends of the lower-layer wirings 11a to 11e are connected to a ground wiring 20, via the fuse elements 10a to 10e, respectively.

As shown in FIG. 14 and FIG. 15, at the time of disconnecting the predetermined fuse element 10c by the laser beam L, a beam spot of the laser beam L is narrowed by the fuse element 10c to have a minimum diameter D₁. However, not all the energy of the laser beam L is absorbed by the fuse element 10c, and a part of the laser beam L is leaked out to a semiconductor substrate outside the fuse element 10c. Because the beam spot of the laser beam L is narrowed to a minimum by the fuse element 10c, the beam spot of the laser beam L becomes larger than D₁ at the semiconductor substrate side than at the fuse element 10c side.

Therefore, when a planar distance between the fuse elements 10a and 10c adjacent in the X direction is short, the laser beam L is irradiated to a peripheral circuit of the fuse element 10a, as shown in FIG. 14 and FIG. 15. In the example shown in FIG. 14 and FIG. 15, the laser beam L is irradiated to a through-hole electrode 12a, when the beam spot of the laser beam L extends to about 2Xp (=D₂). This is similarly applied to the fuse element 10e, and the laser beam L is irradiated to a through-hole electrode 12e, when the beam spot of the laser beam L extends to about 2Xp (=D₂).

In the state that the beam spot is spread, while the energy density of the laser beam L is low, the adjacent thorough-hole electrodes 12a and 12e have a risk of being greatly damaged depending on conditions. For example, when the through-hole electrodes 12a and 12e pierce through a part of an insulation layer having a high light-absorbing rate like a silicon nitride film, the through-hole electrodes 12a and 12e have a risk of being broken at this part. This is similarly applied to the fuse elements 10b and 10d adjacent approximately in the Y direction. When the beam spot of the laser beam L is spread, the laser beam L is irradiated to the through-hole electrodes 12b and 12d.

Therefore, when the layout pitch Xp of the lower-layer wirings 11a to 11e and a distance Yb between the fuse elements in the Y direction adjacent in the X direction are made small, reliability of the semiconductor device decreases. To prevent this problem, the layout pitch Xp in the X direction and the distance Yb in the Y direction can be set wide. However, in this case, the number of fuse elements that can be laid out per unit area decreases.

As explained above, the method of breaking a fuse element by irradiating a laser beam has problems in that reliability decreases when the layout pitch Xp and the distance Yb are narrowed, and that the degree of location becomes low when the layout pitch Xp and the distance Yb are widened.

### SUMMARY OF THE INVENTION

The present invention has been achieved to solve the above problems, and an object of the present invention is to provide an improved semiconductor device having a fuse element that can be disconnected by irradiating a laser beam to this fuse element.

Another object of the present invention is to provide a semiconductor device that can increase the degree of location of fuse elements while securing reliability.

Still another object of the present invention is to provide a semiconductor device giving little influence to fuse elements adjacent to a predetermined fuse element and peripheries of the fuse elements at the time of disconnecting the predetermined fuse element.

The semiconductor device according to the present invention includes: a plurality of fuse elements that can be disconnected by irradiating a laser beam; lower-layer wirings located below the fuse elements; and a plurality of through-hole electrodes connecting between the plurality of fuse elements and the lower-layer wirings, wherein the through-hole electrodes are provided at both ends of the fuse elements in a first direction, and the plurality of fuse elements are laid out substantially on a straight line in the first direction.

Preferably, the semiconductor device according to the present invention is located between the plural fuse elements as viewed two-dimensionally, and includes attenuation members capable of attenuating the laser beam. In this case, the attenuation members are located nearer to the semiconductor substrate side than to the fuse elements. The attenuation members preferably include columnar bodies extending to a direction approximately perpendicular to the semiconductor substrate. The “columnar bodies” include a cylindrical body having a cavity within each columnar body. A diameter of each columnar body does not need to be constant in an axial direction.

According to the present invention, at the time of disconnecting a predetermined fuse element, the through-hole electrodes connected to this fuse element become a shade, and can prevent unnecessary energy of the laser beam from being directly irradiated to other through-hole electrodes. Therefore, a layout pitch of fuse elements can be narrowed while securing reliability. For example, a distance between fuse elements adjacent in a first direction can be set shorter than a length of the fuse elements in the first direction.

When plural through-hole electrodes are provided at both ends of the fuse element in the first direction and also when at least two of the plural through-hole electrodes are laid out substantially in the first direction, the laser beam in the first direction (that is, other adjacent through-hole electrodes) can be shielded more securely.

Further, when the attenuation members are laid out between the plural fuse elements as viewed two-dimensionally, unnecessary energy of the laser beam can be attenuated more effectively. In this case, when columnar bodies extending to a direction approximately perpendicular to the semiconductor substrate are used as attenuation members, the columnar bodies themselves can absorb the energy of the laser beam, and the laser beam can be scattered by Fresnel diffraction. Therefore, the columnar bodies can efficiently attenuate the laser beam, without generating a crack in the insulation film by absorbing excessive energy.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic top plan view showing a configuration of main parts of a semiconductor device according to a first embodiment of the present invention;

FIG. 2 is a schematic cross-sectional view along a line B-B shown in FIG. 1;

FIG. 3 is a schematic top plan view showing a position of a beam spot of the laser beam L;

FIG. 4 is a schematic cross-sectional view along a line C-C shown in FIG. 3;

FIG. 5A is a pattern diagram when the laser beam L is irradiated to a columnar body from one direction;

FIG. 5B is a schematic graph showing an energy distribution of the laser beam L appearing on a straight line shown in FIG. 5A;

FIG. 6 is a schematic cross-sectional view showing a state that the laser beam L is irradiated to the fuse element, when the formation of one of the two through-hole electrodes is defective;

FIG. 7 is a schematic top plan view showing a configuration of main parts of a semiconductor device according to a second embodiment of the present invention;

FIG. 8 is a schematic cross-sectional view along a line G-G shown in FIG. 7;

FIG. 9 is a schematic top plan view showing a position of a beam spot of the laser beam L;

FIG. 10 shows an attenuation member having a plate-like shape;

FIG. 11A is a schematic cross-sectional view showing a configuration of a cylindrical body constituting the attenuation material showing a state before the laser beam L is irradiated;

FIG. 11B is a schematic cross-sectional view showing a configuration of a cylindrical body constituting the attenuation material showing a state that the cylindrical body is deformed by the irradiation of the laser beam L;

FIG. 12 is a schematic top plan view showing a configuration of main parts of a semiconductor device according to one variant embodiment;

FIG. 13 is a schematic cross-sectional view for explaining a method of disconnecting a conventional fuse element by irradiating a laser beam;

FIG. 14 is a top plan view for explaining the influence applied by the laser beam to other fuse elements and to their peripheries; and

FIG. 15 is a schematic cross-sectional view along a line D-D shown in FIG. 14.

### DETAILED DESCRIPTION OF THE EMBODIMENTS

Preferred embodiments of the present invention will now be explained below in detail with reference to the accompanying drawings.

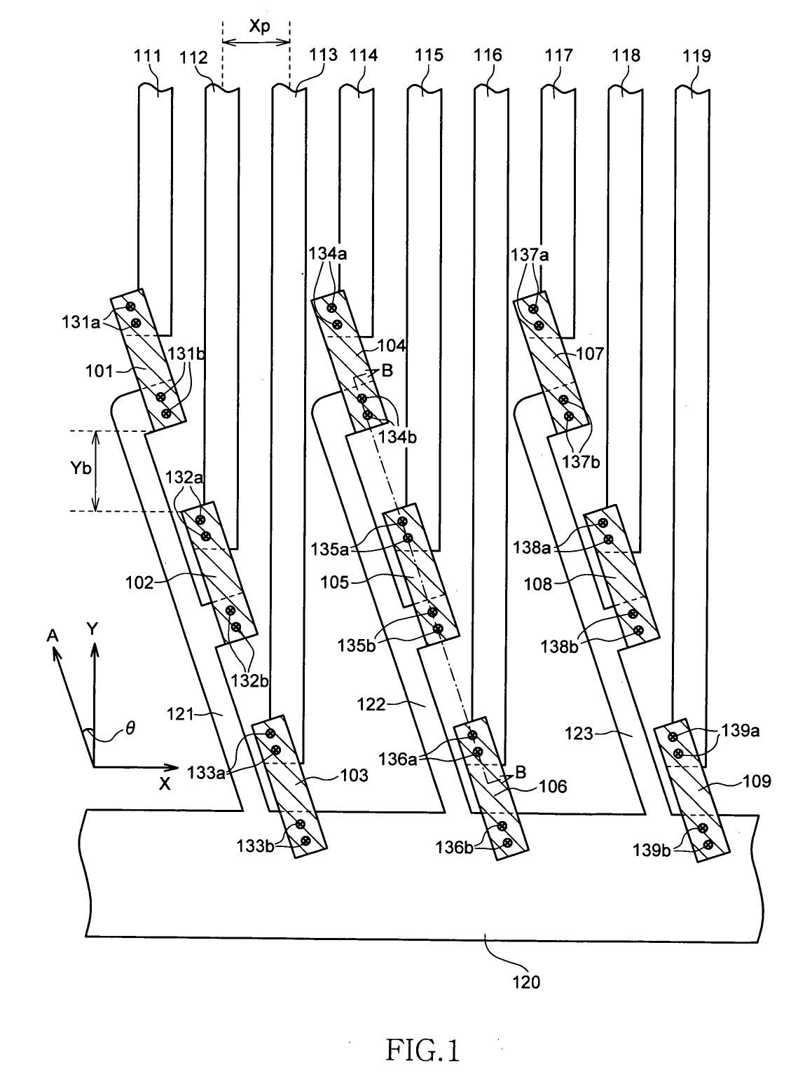

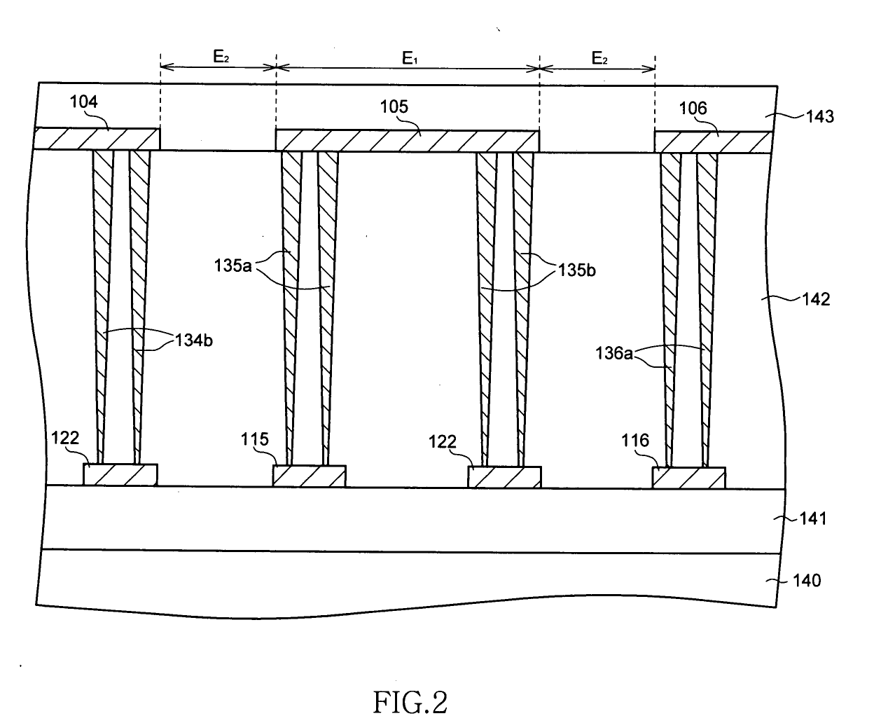

FIG. 1 is a schematic top plan view showing a configuration of main parts of a semiconductor device according to the first embodiment of the present invention. FIG. 2 is a schematic cross-sectional view along a line B-B shown in FIG. 1.

As shown in FIG. 1, the semiconductor device according to the first embodiment has plural fuse elements 101 to 109 laid out in matrix. One ends of the fuse elements 101 to 109 are connected the lower-layer wirings 111 to 119 extending in parallel to the Y direction, respectively. The other ends of the fuse elements 101 to 109 are connected in common to a lower-layer wiring 120 having a fixed potential (for example, a ground potential), via one of lower-layer wirings 121, 122, and 123.

As shown in FIG. 1, the fuse elements 101 to 103 are laid out on substantially a straight line to an A direction as a longitudinal direction. Similarly, the fuse elements 104 to 106 are also laid out on substantially a straight line to the A direction, and the fuse elements 107 to 109 are also laid out on substantially a straight line to the A direction. As shown in FIG. 1, the A direction has a predetermined angle θ with the Y direction to which the lower-layer wirings 111 to 119 are extended. Based on this layout, from the viewpoint of the fuse element 105 at the center, for example, the fuse element 105 is adjacent to the fuse elements 104 and 106 in the A direction, and is adjacent to the fuse elements 102 and 108 in the X direction.

One ends of the fuse elements 101 to 109 are connected to the lower-layer wirings 111 to 119 via through-hole electrodes 131a to 139a, respectively. On the other hand, the other ends of the fuse elements 101 to 109 are connected to the lower-layer wirings 121, 122, and 123, via through-hole electrodes 131b to 139b, respectively. As shown in FIG. 1, the fuse elements 101 to 109 are assigned, at one ends and the other ends, respectively, with each two of the through-hole electrodes 131a to 139a, and 131b to 139b. Accordingly, four through-hole electrodes in total are assigned to each one fuse element. This allocation is made to prevent generation of a conductive failure due to a process variance at the manufacturing time. Therefore, it is not essential to assign two through-hole electrodes to one end and the other end respectively of each of the fuse elements 101 to 109.

In the first embodiment, two of each of the through-hole electrodes 131a to 139a, and 131b to 139b are laid out in the A direction. The through-hole electrodes are laid out in this way to shield more securely the laser beam to the through-hole electrodes adjacent in the A direction.

The through-hole electrodes 131a to 139a, and 131b to 139b are provided piercing through an insulation film 142, as shown in FIG. 2. The insulation film 142 is an interlayer insulation film that separates the lower-layer wirings 111 to 123 from the fuse element 101 to 109, and can include one-layer insulation film, or can be a lamination of plural insulation films. An insulation film 141 that becomes a formation surface of the lower-layer wirings 111 to 123 and an insulation film 143 that covers the fuse element 101 to 109 are formed on the upper surface of the semiconductor substrate 140. The insulation films 141 and 143 can also include one-layer insulation film, or can be a lamination of plural insulation films.

In the semiconductor device according to the first embodiment, in the state before the fuse elements 101 to 109 are disconnected, the corresponding lower-layer wirings 111 to 119 and the lower-layer wiring 120 are in the conductive state. However, when the fuse elements 101 to 109 are disconnected, the corresponding lower-layer wirings 111 to 119 and the lower-layer wiring 120 become in the insulation state. Because the connection state of the lower-layer wirings 111 to 119 can be irreversibly changed, a defective address and the like can be stored permanently.

In the semiconductor device according to the first embodiment, as shown in FIG. 2, a distance E₂ between the fuse elements adjacent in the A direction is shorter than a length E₁ of the fuse element in the longitudinal direction. In this way, in the semiconductor device according to the first embodiment, the fuse elements are laid out in high density.

A method of disconnecting the fuse element is explained next.

In the present embodiment, the fuse elements 101 to 109 are disconnected by irradiating a laser beam.

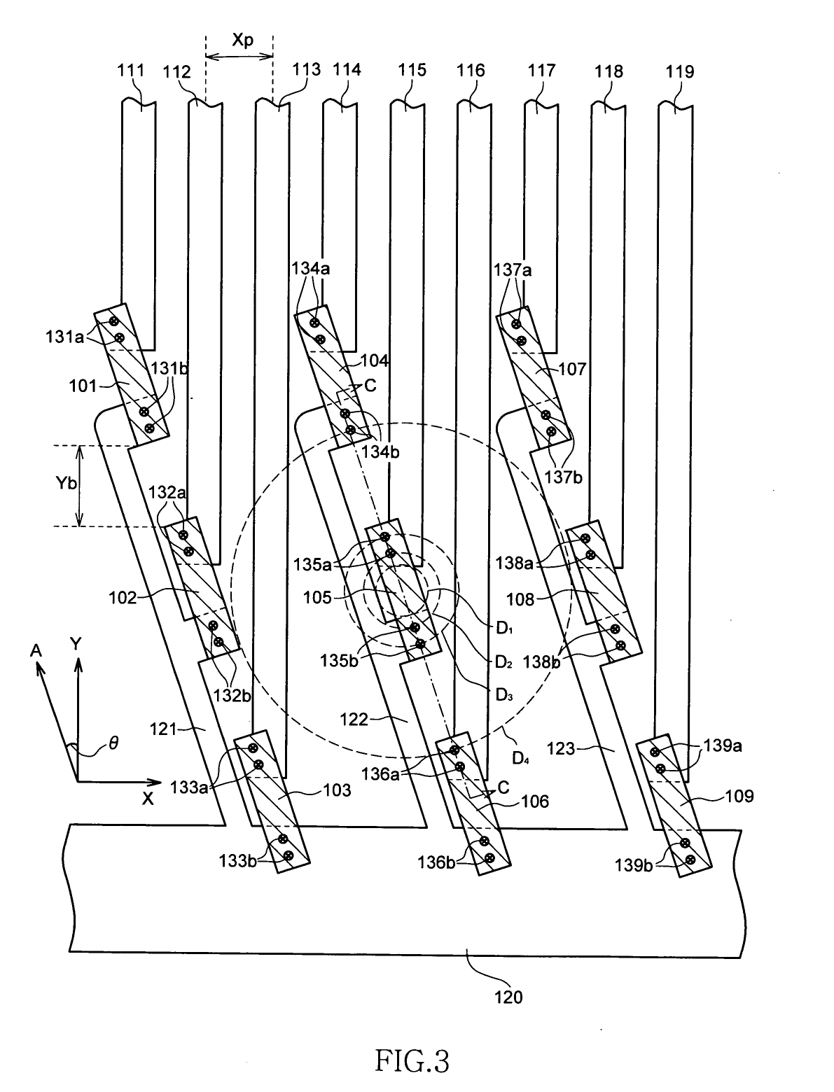

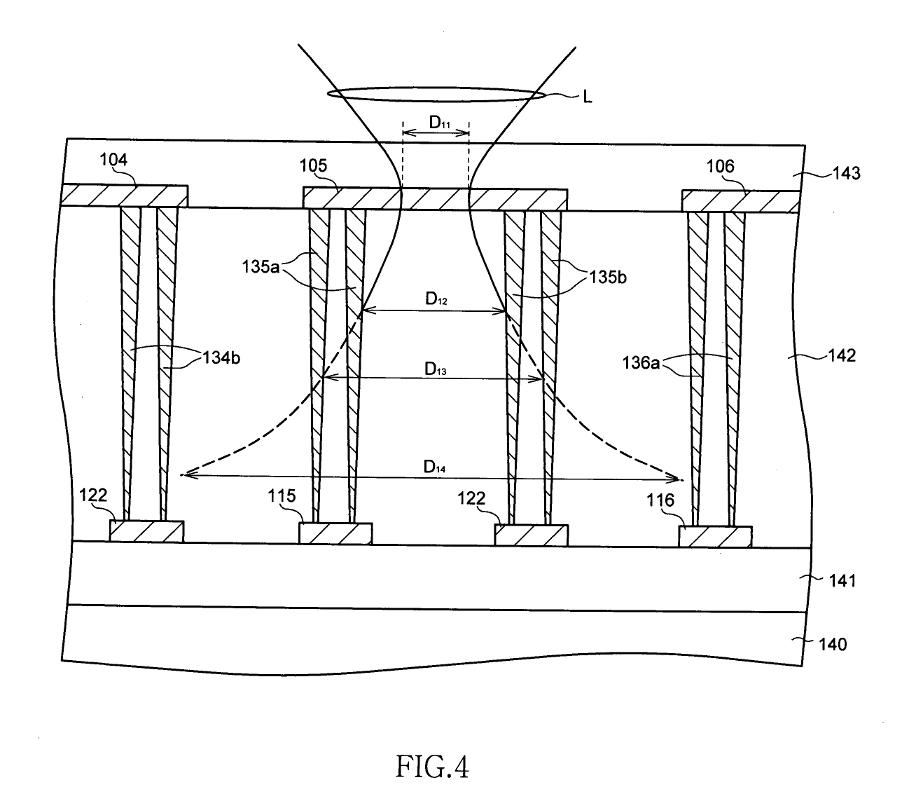

FIG. 3 is a schematic top plan view showing a position of a beam spot of the laser beam L which is irradiated at the time of disconnecting the fuse element 105. FIG. 4 is a schematic cross-sectional view along a line C-C shown in FIG. 3.

As shown in FIG. 3 and FIG. 4, to disconnect the fuse element 105, the laser beam L is irradiated to the fuse element 105 from above the fuse element 105. In this case, the laser beam L is converged to include the fuse element 105 within a focal depth of the laser beam L, using an optical lens (not shown). A beam spot of the laser beam L becomes the smallest (=D₁₁), within the focal depth. Accordingly, most of the energy of the laser beam L is absorbed by the fuse element 105, and heat energy is concentrated to the fuse element 105, thereby disconnecting the fuse element 105.

As explained above, because not all energy of the laser beam L is absorbed by the fuse element 105, a part of the laser beam L leaks out to the semiconductor substrate 140 from the fuse element 105. Because the beam spot of the laser beam L is narrowed to a minimum size by the fuse element 105 as described above, the beam spot of the laser beam L becomes larger than D₁₁, at the semiconductor substrate side than on the fuse element 105.

The laser beam L leaked out to the semiconductor substrate 140 from the fuse element 105 (to the side away from the optical lens) is irradiated to through-hole electrodes 135a and 135b at the inside when the diameter of the beam spot is increased to D₁₂. Accordingly, a part of the leaked energy of the laser beam L is absorbed by the through-hole electrodes 135a and 135b. Further, when the diameter of the beam spot of the laser beam increases to D₁₃, the laser beam L is irradiated to the through-hole electrodes 135a and 135b at the outside. Therefore, other part of the leaked energy of the laser beam L is absorbed by the through-hole electrodes 135a and 135b.

When the diameter of the beam spot of the laser beam L becomes equal to or larger than D₁₄, conventionally, the laser beam L is directly irradiated to through-hole electrodes 134b and 136a adjacent in the A direction. However, out of the leaked energy of the laser beam L, a component leaded out to the A direction is absorbed by the through-hole electrodes 135a and 135b. Therefore, the energy applied to the through-hole electrodes 134b and 136a becomes very small. In other words, the through-hole electrodes 134b and 136a are located at the shade position of the through-hole electrodes 135a and 135b, for the laser beam L. Consequently, the leaked laser beam L is not directly irradiated to the through-hole electrodes 134b and 136a. However, because the through-hole electrodes 135a and 135b generate the Fresnel diffraction, the energy of the laser beam L irradiated to the through-hole electrodes 134b and 136a is not zero.

As described above, according to the first embodiment, the through-hole electrodes connected to the fuse element to be disconnected form a “shade” in the through-hole electrodes adjacent in the A direction. Therefore, damage received by the adjacent through-hole electrodes is much smaller than conventional damage. This means that the distance E₂ between the fuse elements adjacent in the A direction can be decreased while securing reliability, as compared with the conventional practice. Specifically, the distance E₂ between the fuse elements adjacent in the A direction can be set shorter than the length E₁ of the fuse element in the longitudinal direction.

Further, the area which becomes the shade of the through-hole electrodes is the one where the energy of the laser beam L is weakened by the interference due to the Fresnel diffraction. The energy irradiated to this area becomes smaller than the energy irradiated to other area.

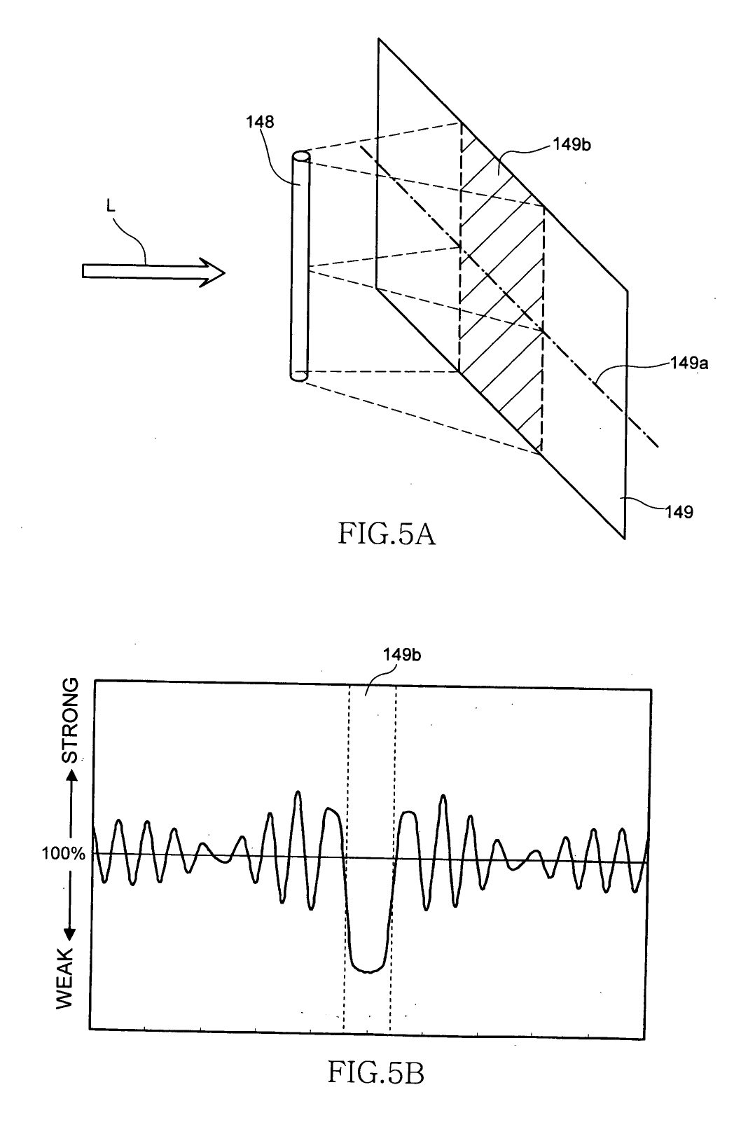

That is, when the laser beam L is irradiated to a columnar body 148 from one direction as shown in FIG. 5A, and when the diameter of the columnar body 148 is sufficiently smaller than the wavelength of the laser beam L, an interference pattern appears by diffraction on a plane surface 149 located at the back of the columnar body 148. FIG. 5B is a schematic graph showing an energy distribution of the laser beam L appearing on a straight line 149a on the plane surface 149. In FIG. 5B, the intensity of the laser beam L when the columnar body 148 is not present is expressed as 100%.

As shown in FIGS. 5A and 5B, in the area 149b which becomes the shade of the columnar body 148, the energy is weakened by the interference of the Fresnel diffraction. Therefore, the intensity of the laser beam L becomes very low within this area 149b.

As described above, according to the first embodiment, the through-hole electrodes are laid out in line in the A direction. Therefore, one through-hole electrode is located in the shade of the other through-hole electrode without exception. That is, one through-hole electrode protects the other through-hole electrode, and the interference due to the Fresnel diffraction can be used efficiently.

As explained above, according to the first embodiment, because the distance E₂ between the fuse elements adjacent in the A direction can be decreased while securing reliability, the distance Yb in the Y direction can be decreased. Therefore, according to the first embodiment, the fuse elements can be laid out in high density while securing reliability.

The layout pitch Xp and the distance Yb in the Y direction of the lower-layer wirings 111 to 119 can be adjusted by the angle θ formed by the A direction and the X direction. Specifically, when the angle θ is set small, the layout pitch Xp becomes small, and the distance Yb becomes long. On the other hand, when the angle θ is set large, the layout pitch Xp becomes large, and the distance Yb becomes short. Therefore, the formation density of the fuse elements can be maximized while securing reliability, by suitably adjusting the angle θ based on various conditions such as the length E₁ of the fuse element and the height of the through-hole electrode.

In the first embodiment, while the fuse elements are laid out in the A direction having the predetermined angle θ relative to the Y direction, the present invention is not limited to this layout. Therefore, the fuse elements can be laid out in the Y direction to which the lower-layer wirings 111 to 119 are extended.

However, when the fuse elements are laid out in the Y direction, the lower-layer wirings need to be diverted to some extent in order to avoid interference between the lower-layer wirings 111 to 119 and the lower-layer wirings 121 to 123. On the other hand, like in the first embodiment, when the fuse elements are laid out aslant to the Y direction, and also when two adjacent lower-layer wirings (the lower-layer wiring 111 and the lower-layer wiring 112, for example) are connected to one ends of two fuse elements adjacent in the A direction (the fuse element 101 and the fuse element 102, for example), respectively, the interference can be avoided without moving the lower-layer wiring. Therefore, when the fuse elements are laid out aslant to the Y direction like in the first embodiment, the occupied area can be decreased as compared with the area when the fuse elements are laid out in the Y direction.

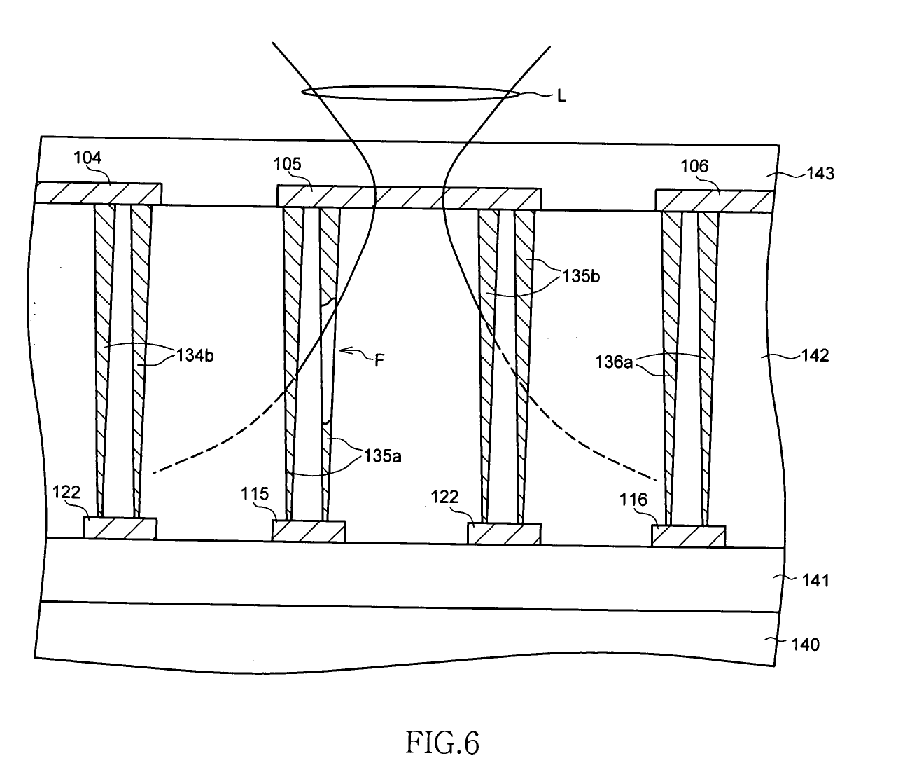

In the first embodiment, because two of each of the through-hole electrodes 131a to 139a, and 131b to 139b are laid out in the A direction, a laser beam to the through-hole electrodes adjacent in the A direction can be shielded more securely. FIG. 6 is a schematic cross-sectional view showing a state that the laser beam L is irradiated to the fuse element 105, when the formation of one of the two through-hole electrodes 135a is defective.

In the example shown in FIG. 6, out of the two through-hole electrodes 135a, the through-hole electrode located inside is formed defectively. Therefore, a cavity F in which no through-hole electrode is present is formed. In this case, the attenuation of the laser beam L by the through-hole electrode becomes insufficient. However, in the first embodiment, because another through-hole electrode is laid out in the A direction, the energy of the laser beam L irradiated to the adjacent through-hole electrode 134b can be sufficiently decreased. That is, when the two through-hole electrodes are used, not only backup effect of the conductive failure can be obtained but also backup effect of the shielding of the laser beam L can be obtained.

A second embodiment of the present invention is explained next.

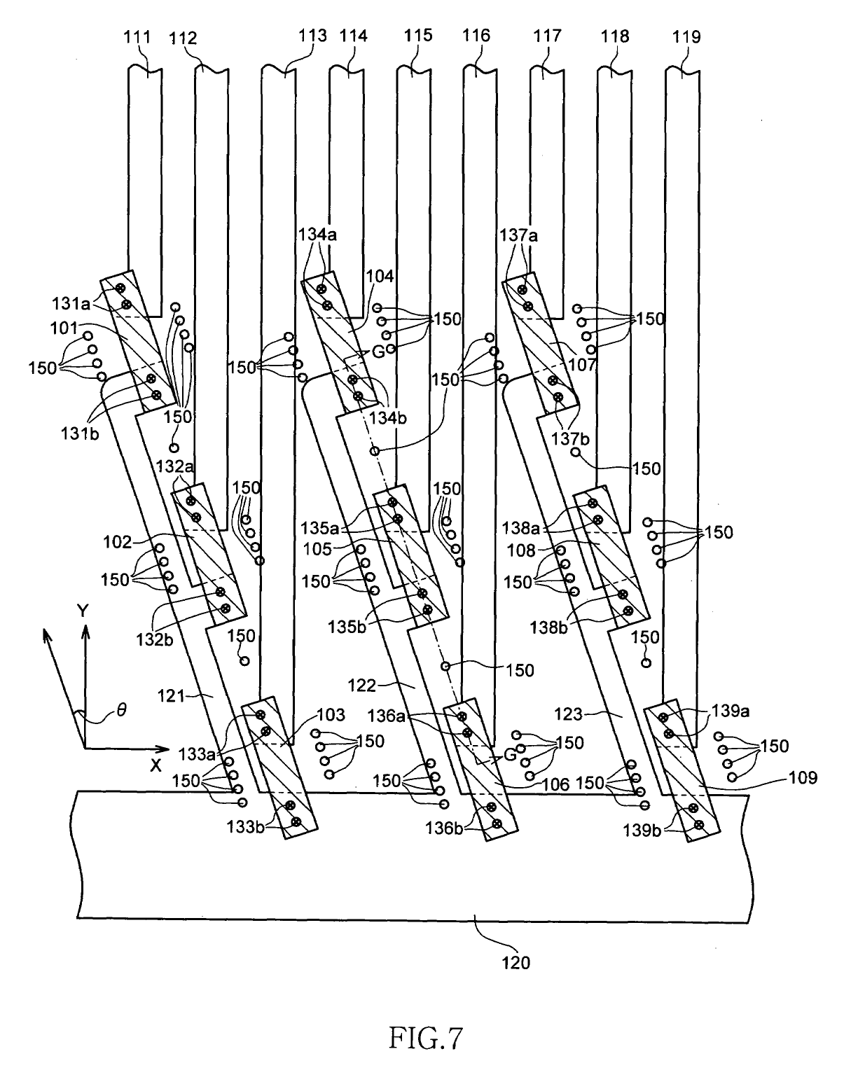

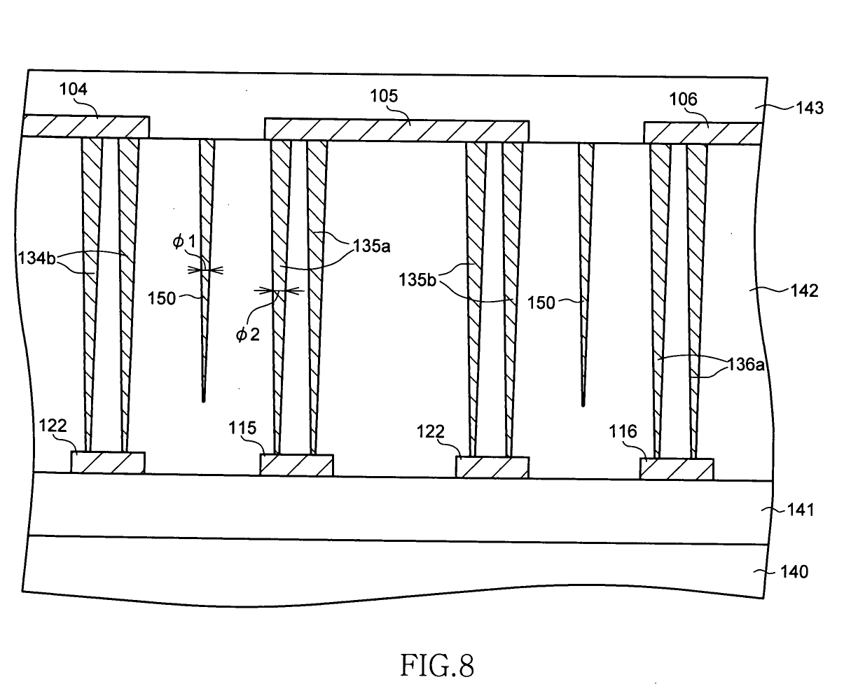

FIG. 7 is a schematic top plan view showing a configuration of main parts of a semiconductor device according to the second embodiment. FIG. 8 is a schematic cross-sectional view along a line G-G shown in FIG. 7.

As shown in FIG. 7, the semiconductor device according to the second embodiment is different from the semiconductor device according to the first embodiment in that attenuation members 150 that can attenuate a laser beam are laid out around the fuse elements 101 to 109 as viewed two-dimensionally. The semiconductor device according to the second embodiment is the same as the semiconductor device according to the first embodiment in other points. Therefore, like constituent elements are denoted by like reference numerals, and redundant explanations thereof will be omitted. Note that the “viewed two-dimensionally” means “viewed from a direction approximately perpendicular to the main surface of the semiconductor substrate 140”.

In the second embodiment, the attenuation members 150 are constituted by a plurality of columnar bodies. As shown in FIG. 8, the columnar bodies constituting the attenuation members 150 are embedded into the insulation film 142, and extend to a direction approximately perpendicular to the semiconductor substrate 140. As explained above, the attenuation members 150 are provided in the same layers as those of the through-hole electrodes 131a to 139a and 131b to 139b. With this arrangement, the whole attenuation members 150 are located nearer to the semiconductor substrate 140 side than to the fuse elements 101 to 109. The columnar bodies constituting the attenuation members 150 are made of the same conductive material (for example, tungsten) as that of the through-hole electrodes 131a to 139a and 131b to 139b. While the columnar bodies constituting the attenuation members 150 do not need to be made of the same conductive material as that of the through-hole electrodes 131a to 139a and 131b to 139b, when these are the same conductive materials, the attenuation members 150 and the through-hole electrodes 131a to 139a and 131b to 139b can be manufactured in the same process.

As shown in FIG. 8, the length (height) of the columnar bodies constituting the attenuation members 150 is smaller than that of the through-hole electrodes 131a to 139a and 131b to 139b. Therefore, even when the columnar bodies are laid out immediately above the lower-layer wirings 111 to 123, the columnar bodies are not in contact with the lower-layer wirings 111 to 123, and are insulated. In the present embodiment, the attenuation members 150 is not in contact with any conductive pattern, and therefore, is electrically in a floating state.

Diameters φ1 of the columnar bodies constituting the attenuation members 150 are set smaller than diameters φ2 of the through-hole electrodes 131a to 139a and 131b to 139b. This is because when the diameter of the through-hole into which the attenuation member 150 is embedded is made small at the time of forming the through-hole by etching the insulation film 142, the depth of this through-hole can be made smaller (or, the height can be made smaller) than the through-hole for forming the through-hole electrodes 131a to 139a and 131b to 139b. Because the through-hole into which the attenuation member 150 is embedded and the through-hole for forming the through-hole electrodes 131a to 139a and 131b to 139b can be formed by etching the insulation film 142 in this way, the diameter is larger upward and is smaller downward. Therefore, the diameter φ1 of the columnar body can be compared with the diameter φ2 of the through-hole electrode at approximately the center of each height in the height direction.

As shown in FIG. 7, the columnar bodies constituting the attenuation members 150 are laid out between fuse elements adjacent in the A direction, and are also laid out between fuse elements adjacent in the X direction.

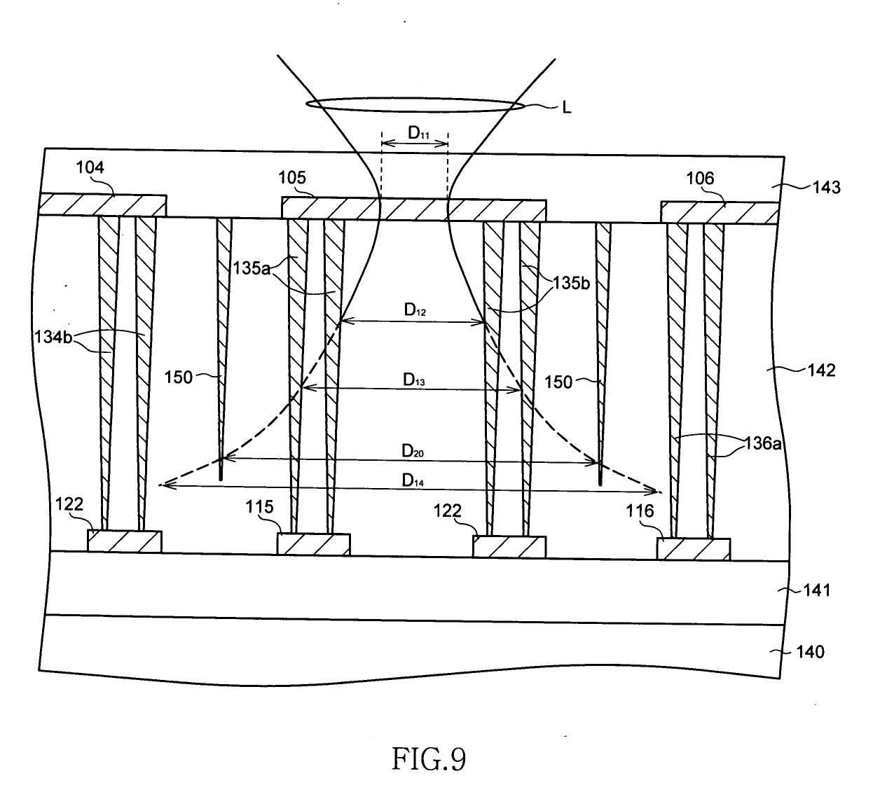

FIG. 9 is a schematic cross-sectional view showing a position of the beam spot of the laser beam L irradiated at the time of disconnecting the fuse element 105. FIG. 9 corresponds to FIG. 4 showing a position of the beam spot in the first embodiment.

In the second embodiment, the attenuation members 150 are laid out between adjacent fuse elements. Therefore, the laser beam L is irradiated to the attenuation members 150, based on the increase of the diameter of the beam spot of the laser beam L to D₂₀. That is, the energy of the laser beam L spread to the A direction as viewed two-dimensionally is absorbed by both the through-hole electrodes 135a and 135b and the attenuation members 150. Accordingly, the energy applied to the through-hole electrodes 134b and 136a adjacent in the A direction becomes smaller.

Because the attenuation members 150 are also laid out in the X direction viewed from the fuse elements, the energy applied to the through-hole electrodes adjacent in the X direction viewed from the fuse element to be disconnected also becomes small.

Therefore, damage applied to the adjacent through-holes can be further decreased, and the formation density of the fuse elements can be further increased.

Advantages of using the columnar body as the attenuation member 150 are explained below.

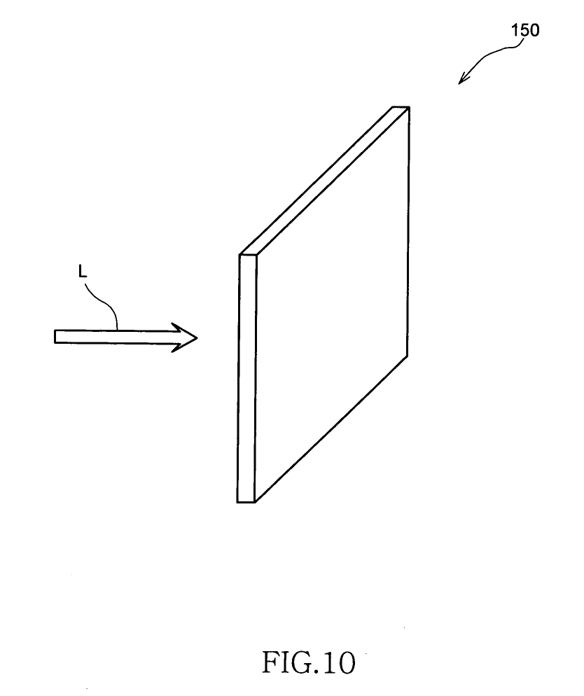

To effectively attenuate the laser beam L leaked out from the fuse element to the semiconductor substrate 140, a plate-like body shown in FIG. 10 is used instead of the columnar body as the attenuation member 150. However, when the columnar body is used as the attenuation member 150, most of the leaked energy of the laser beam L is absorbed by the attenuation member 150. Therefore, the attenuation member 150 is swollen by overheating some times, and the surrounding insulation film has a risk of being broken as a result.

As described above, the attenuation member 150 is not connected to any conductive pattern, and is electrically in the floating state. Therefore, the attenuation member 150 itself may be broken. However, when the attenuation member 150 is swollen to crack the insulation film, there is a risk of the occurrence of an insulation failure and immersion of water, resulting in a reduction of the reliability of the device.

On the other hand, when the columnar body is used as the attenuation member 150 like in the present embodiment, this risk can be decreased. That is, when the columnar body is used as the attenuation member 150, the energy of the laser beam L absorbed by the attenuation member 150 is reduced compared to the plate-like body shown in FIG. 10. Therefore, breaking of the insulation film can be prevented, and the laser beam L can be effectively shielded.

To effectively prevent the breaking of the insulation film, it is most preferable to provide a cavity inside the columnar body. That is, the attenuation member 150 preferably includes a cylindrical body.

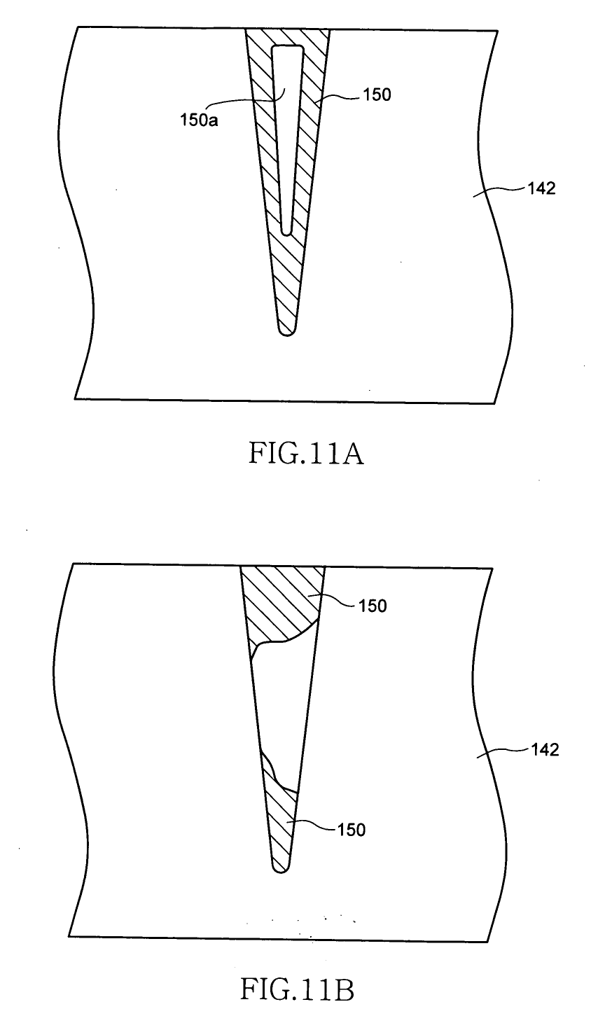

FIGS. 11A and 11B are schematic cross-sectional views showing a configuration of a cylindrical body constituting the attenuation material 150: FIG. 11A shows a state before the laser beam L is irradiated; and FIG. 11B shows a state that the cylindrical body is deformed by the irradiation of the laser beam L.

As shown in FIG. 11A, when the attenuation member 150 includes a cylindrical body, a cavity 150a encircled by the attenuation member 150 is present. This cavity 150a plays a role of absorbing expansion energy when the laser beam L is irradiated. That is, when the laser beam L is irradiated to the attenuation member 150 as the cylindrical body, the attenuation member 150 is expanded and deformed within the through-hole without breaking the insulation film 142, as shown in FIG. 11B. When the attenuation member 150 includes a cylindrical body in this way, damage to the insulation film can be decreased, even when the attenuation member 150 is expanded and deformed by the energy of the laser beam L.

This cylindrical body can be formed by depositing the attenuation member 150 by the process of low coverage, after the through-hole is formed in the insulation film 142. When the process of high coverage is used, a cavity unavoidably remains when the aspect ratio of the through-hole is large, and the cylindrical body can be manufactured using this.

As explained above, according to the semiconductor device of the second embodiment, the attenuation members 150 including plural cylindrical bodies are laid out between adjacent fuse elements, as viewed two-dimensionally. Therefore, the laser beam L leaked out to below the fuse element to be broken can be absorbed and scattered. Accordingly, at the time of disconnecting a predetermined fuse element, the influence given to the adjacent fuse elements and their peripheries can be decreased. Consequently, the layout pitch of the fuse elements can be made small while securing reliability.

While a preferred embodiment of the present invention has been described hereinbefore, the present invention is not limited to the aforementioned embodiment and various modifications can be made without departing from the spirit of the present invention. It goes without saying that such modifications are included in the scope of the present invention.

In the second embodiment, while the diameter φ1 of each attenuation member 150 as the columnar body is set smaller than the diameter φ2 of each of the through-hole electrodes 131a to 139a and 131b to 139b, these diameters can be set the same. The diameter φ1 of each attenuation member as the columnar body is set smaller than the diameter φ2 of each of the through-hole electrodes 131a to 139a and 131b to 139b, to prevent the attenuation members 150 from being in contact with the lower-layer wirings 111 to 123, as described above. When this contact can be prevented by other method, the diameter of the attenuation member 150 does not need to be smaller.

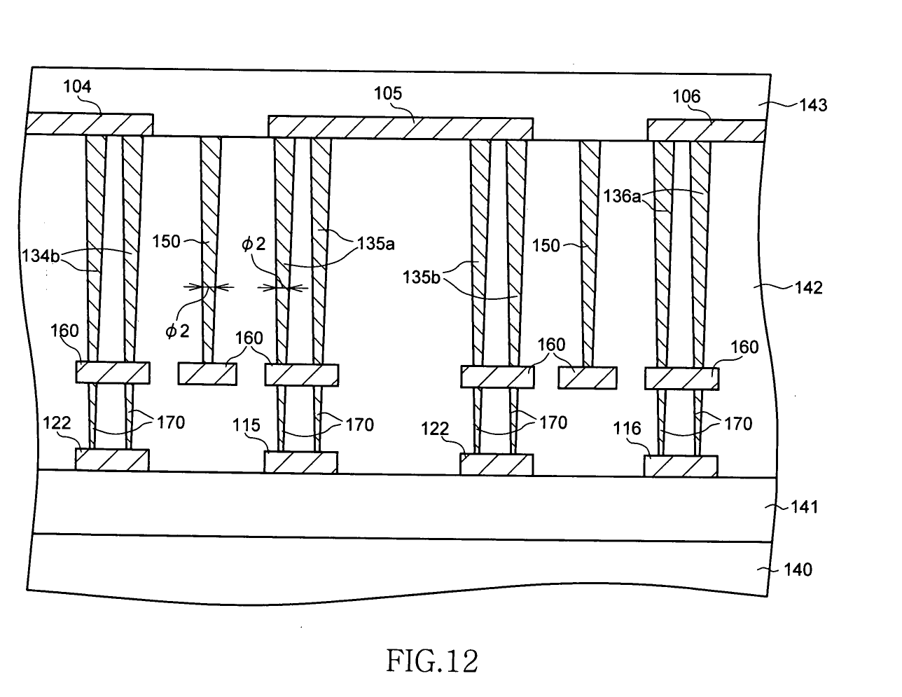

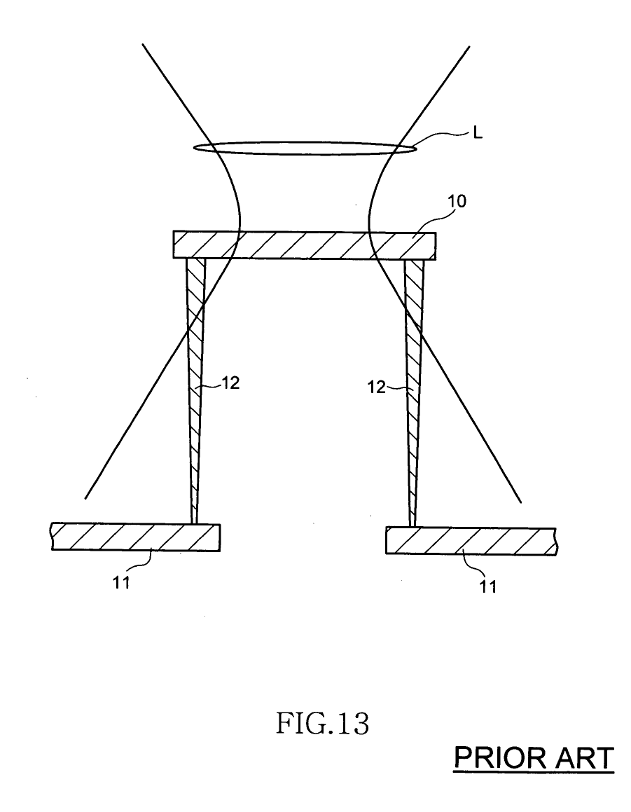

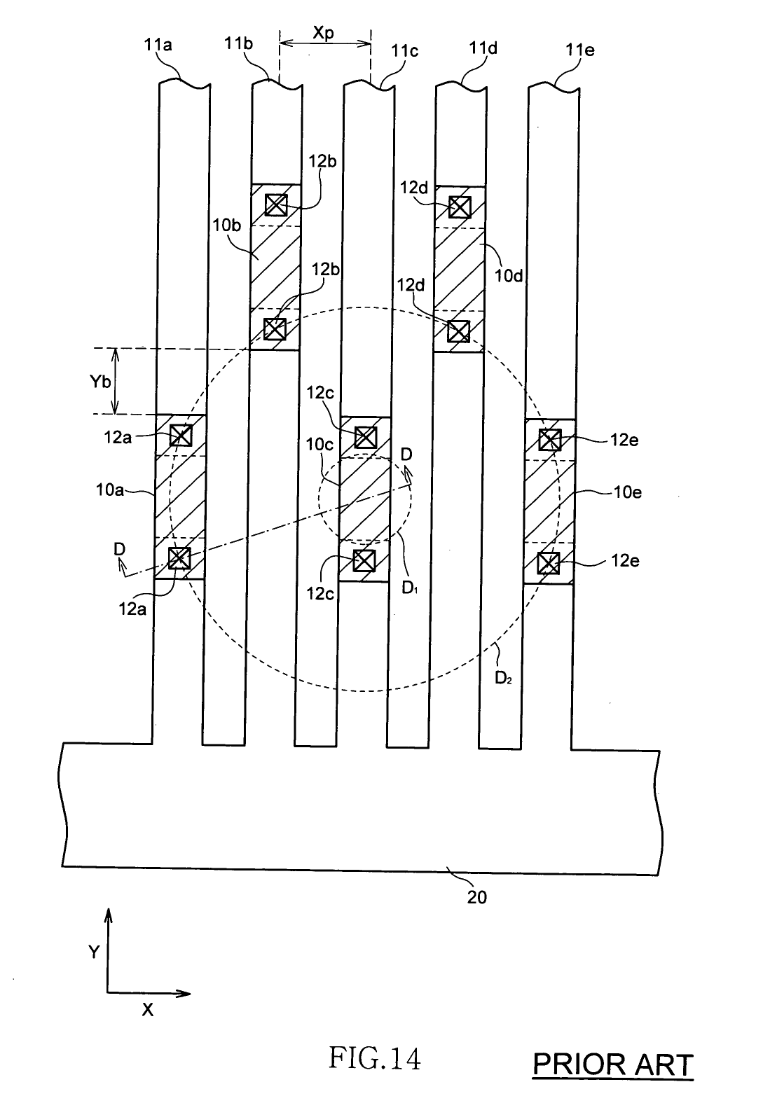

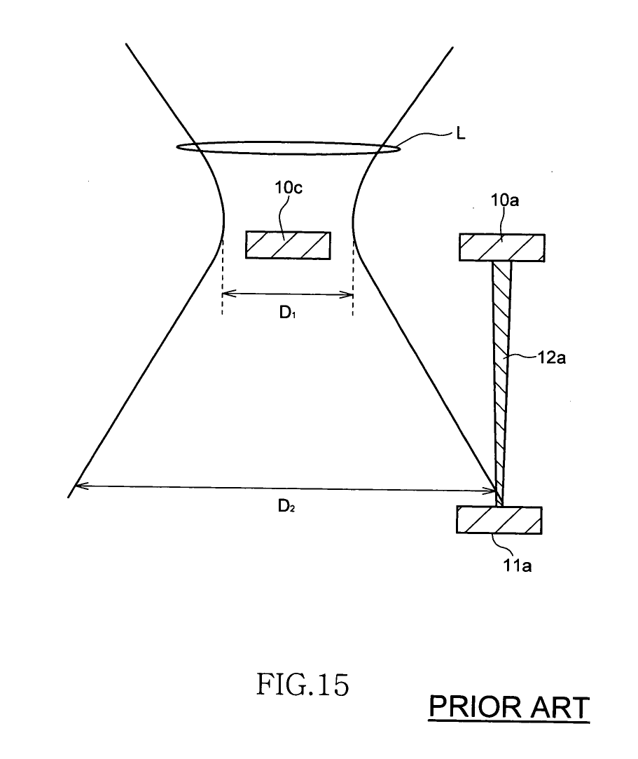

As shown in FIG. 12, intermediate wirings 160 can be provided between the fuse elements 101 to 109 and the lower-layer wirings 111 to 123, respectively. Through-hole electrodes 170 for connecting between the intermediate wirings 160 and the lower-layer wirings 111 to 123 respectively are formed at parts corresponding to the through-hole electrodes 131a to 139a and 131b to 139b. On the other hand, these through-hole electrodes can be omitted at parts corresponding to the attenuation members 150.

Further, in the second embodiment, while one or more columnar bodies constituting the attenuation members 150 are laid out in a row between the adjacent fuse elements 101 to 109, the columnar bodies constituting the attenuation members 150 can be dispersed between the adjacent fuse elements 101 to 109. When the columnar bodies constituting the attenuation members 150 are dispersed, the non-absorbed laser beam L is scattered minutely by the Fresnel diffraction. Consequently, the laser beam L can be effectively shielded while preventing breaking of the insulation film.

To sufficiently obtain the scattering effect by the Fresnel diffraction while preventing breaking of the insulation film, preferably, diameters φ1 of the columnar bodies are set smaller than the wavelength of the laser beam L. For example, when the wavelength of the laser beam L is about 1,000 nm, the diameters φ1 of the columnar bodies can be set to about 200 nm.

In the second embodiment, while the attenuation members 150 use the same material as that of the through-hole electrodes 131a to 139a and 131b to 139b, the material of the attenuation members 150 is not limited to this. Other materials having higher light-absorption rate than that of the insulation film 142 can be also used for the attenuation members 150. Therefore, the material of the attenuation member 150 does not need to be a conductive material, and can be an insulation material having a high light-absorption rate (for example, silicon nitride). When the attenuation members 150 use the same material as that of the through-hole electrodes 131a to 139a and 131b to 139b like in the above embodiment, the attenuation members 150 and the through-hole electrodes 131a to 139a and 131b to 139b can be manufactured in the same process, thereby generating no cost increase.

In the first and second embodiments, while the longitudinal direction of the fuse elements coincides with the A direction as the layout direction, this is not essential in the present invention, and the plane shape of the fuse elements can be square, for example.

What is claimed is:

1. A semiconductor device comprising:
a plurality of fuse elements that can be disconnected by irradiating a laser beam;
lower-layer wirings located below the fuse elements; and
a plurality of through-hole electrodes connecting between the plurality of fuse elements and the lower-layer wirings,
wherein the through-hole electrodes are provided at both ends of the fuse elements in a first direction, and the plurality of fuse elements are laid out substantially on a straight line in the first direction.

2. The semiconductor device as claimed in claim 1, wherein a distance between fuse elements adjacent in the first direction is shorter than a length of the fuse element in the first direction.

3. The semiconductor device as claimed in claim 1, wherein a plurality of the through-hole electrodes are provided at both ends of the fuse elements in the first direction, and at least two of the plurality of through-hole electrodes are laid out substantially in the first direction.

4. The semiconductor device as claimed in claim 1, wherein the lower-layer wirings include a plurality of parallel wiring patterns extending to a second direction having a predetermined angle with the first direction.

5. The semiconductor device as claimed in claim 4, wherein out of the plurality of parallel wiring patterns, two adjacent wiring patterns are connected to one end of two fuse elements respectively adjacent in the first direction.

6. The semiconductor device as claimed in claim 5, wherein the other end of the two fuse elements respectively is short-circuited via the lower-layer wirings.

7. The semiconductor device as claimed in claim 1, further comprising attenuation members that are located between the plurality of fuse elements as viewed two-dimensionally and that can attenuate the laser beam.

8. The semiconductor device as claimed in claim 7, wherein the attenuation members are located nearer to a semiconductor substrate than to the plurality of fuse elements.

9. The semiconductor device as claimed in claim 8, wherein the attenuation members include columnar bodies extending to a direction approximately perpendicular to the semiconductor substrate.

10. The semiconductor device as claimed in claim 9, wherein at least a part of the columnar bodies is provided in the same layer as that of the through-hole electrodes.

11. The semiconductor device as claimed in claim 10, wherein the columnar bodies are constituted by the same conductive material as that of the through-hole electrodes.

12. The semiconductor device as claimed in claim 11, wherein the columnar bodies are cylindrical bodies having a cavity therein.

13. The semiconductor device as claimed in claim 11, wherein the columnar bodies are insulated from at least the lower-layer wirings.

14. The semiconductor device as claimed in claim 11, wherein a diameter of each columnar body are smaller than a diameter of each through-holes electrode.

15. The semiconductor device as claimed in claim 9, wherein a diameter of the columnar bodies is smaller than a wavelength of the laser beam.
